(19) United States
(12) Patent Application Publication
(10) Pub. No.: US 2026/0238213 A1
(43) Pub. Date: Aug. 13, 2026

(54) Logic device and logic computation architecture

(71) Applicants: THALES, COURBEVOIE (FR); Commissariat à l’Energie Atomique et aux Energies Alternatives, PARIS (FR); Centre national de la recherche scientifique, PARIS (FR); UNIVERSITE GRENOBLE ALPES, SAINT MARTIN D’HERES (FR)

(72) Inventors: Manuel BIBES, PALAISEAU (FR); Julien BRÉHIN, PALAISEAU (FR); Laurent VILA, GRENOBLE CEDEX 9 (FR); Jean-Philippe ATTANE, GRENOBLE CEDEX 9 (FR)

(21) Appl. No.: 18/852,454

(22) PCT Filed: Mar. 29, 2023
(86) PCT No.: PCT/EP2023/058167

§ 371 Date: Apr. 5, 2025

(30) Foreign Application Priority Data
Mar. 30, 2022 (FR) FR2202874

(51) Int. Cl. H03K 19/16; H03K 19/08

(52) U.S. Cl. CPC H03K 19/16; H03K 19/08

(57) ABSTRACT

The present invention relates to a logic device including a first and a second arm through which a charging current passes, a channel that connects the arms and includes a first zone of contact with the first arm, and a second zone of contact with the second arm, the arms and the channel being able, in the first zone of contact, to convert a charging current into a spin current and, in the second zone of contact, to convert a spin current into a charging current, and a unit for controlling the direction of the charging current in the second arm, the control unit including a sub-unit for electrical control of a conversion.

### CROSS-REFERENCE TO RELATED APPLICATIONS

This application claims benefit under 35 USC § 371 of PCT Application N. PCT/EP2023/058167 entitled LOGIC DEVICE AND LOGIC COMPUTATION ARCHITECTURE, filed on Mar. 29, 2023 by inventors Manuel Bibes, Julien Brehin, Laurent Vila and Jean-Philippe Attane. PCT Application No. PCT/EP2023/058167 claims priority of French Patent Application No. 22 02874, filed on Mar. 30, 2022.

### FIELD OF THE INVENTION

The present invention relates to a logic device and logic computation architecture.

The present invention belongs to the field of computation and Boolean logic architectures.

### BACKGROUND OF THE INVENTION

To perform the processing of binary information, it is favorable that the logic devices can have an output that is either positive or negative. Since the output is usually a current, such property can be called “bidirectionality”, so that a logic device can be called a bidirectional logic device.

The processing of binary information is currently performed by CMOS components the output voltage level of which, either low or high, corresponds to a 0 or a 1. CMOS is the abbreviation of “Complementary Metal Oxide Semiconductor”. However, according to the terminology introduced earlier, such components can be called “unidirectional” because, since said components only operate with positive voltages, the current always flows in the same direction.

There is thus an advantage for bidirectional logic devices enabling in particular a concatenation of a plurality devices.

### SUMMARY OF THE DESCRIPTION

To this end, the description describes a logic device comprising:
a first arm, the first arm extending along a first direction, the first arm being adapted to let a charging current flow therethrough,
a second arm, the second arm extending along the first direction, the second arm also being adapted to let a charging current flow therethrough,
a channel connecting the first arm to the second arm, the channel being in a second direction, the second direction being perpendicular to the first direction, the channel including three zones, a first zone of contact with the first arm, a second zone of contact with the second arm and a central zone connecting the two zones of contact, the first arm, the second arm and the channel being adapted to perform a first conversion in the first zone of contact and a second conversion in the second zone of contact, the first conversion being the conversion of a charging current flowing through the first arm, into a spin current flowing through the channel, and the second conversion being the conversion of a spin current flowing through the channel, into a charging current flowing through the second arm, and
a unit for controlling the direction of the charging current flowing in the second arm, the control unit including at least one electrical control sub-unit of one of the two conversions.

In such context, a channel has a dimension along the first direction that is smaller than the dimension of the arms along the first direction.

Similarly, the channel has a substantially elongate shape along the second direction, so that the dimension of the channel along the second direction is generally greater than the dimension of the arms along the second direction.

Thereof means that the channel and the two arms serve to define a substantially planar structure and not a stack of layers.

Thereof makes it possible to achieve a concatenation different from the concatenation that is possible with unidirectional devices such as CMOS components.

Moreover, such a device serves to reduce the electrical consumption of computational architectures compared with same based on CMOS components, by bringing in new computational paradigms and ferroic elements imparting a non-volatile character.

According to other particular embodiments, the logic device has one or a plurality of the following features, taken individually or according to all technically possible combinations:
a control sub-unit is a control sub-unit of the first conversion and is adapted to control the direction of the charging current flowing through the second arm by controlling the direction of the spin current spins by an electrical control of the first conversion.
the control sub-unit for the first conversion includes a voltage source and an electrical contact, the electrical contact being in contact with the first contact zone, the voltage source controlling the potential of the electrical contact.
a control sub-unit is a control sub-unit of the second conversion and is adapted to control the direction of the charging current by an electrical control of the second conversion.
the control sub-unit for the second conversion includes a voltage source and an electrical contact, the electrical contact being in contact with the second contact zone, the voltage source controlling the potential of the electrical contact.
the electrical contact is a multilayer formed at least by an insulating layer and a metal layer, the insulating layer resting on the arm and the channel and preferably being made of a ferroelectric material, the ferroelectric material advantageously being chosen from the list consisting of BaTiO₃, Pb(Zr, Ti)O₃, BiFeO₃, (Hf, Zr)O₂, and poly (vinylidene fluoride).
the electrical contact rests on the channel part and the arm part.
the arms and the channel form an H.
the arms and the channel are made of the same material.
the arms are made of a first material, the contact zones being made of a second material and the channel being made of a third material distinct from the first material and from the second material.
each material is chosen from:
   an oxide, more particularly SrTiO₃ or KTaO₃,
   a III-V semiconductor material, preferably InAs or InSb,
   a II-VI semiconductor material, preferably HgTe or CdTe,
   transition metal dichalcogenides, preferably S₂, WSe₂, PtSe₂, MoTe₂ or MoSe₂, and
   topologic insulators, preferably (Bi,Sb)₂(Se,Te)₃.
the logic device is adapted to perform a logic operation on two logic inputs to obtain a logic output, the state of the logic output being the direction of the current flowing through the second arm, the logic state of a first input being the value of a potential applied to a sub-control unit and the logic state of a second input being the direction of the current flowing through the first arm or the logic state of a first input being the value of a current applied on a control sub-unit and the logic state of a second input being the value of another current applied on a sub-control unit, or the logic state of a second input being the value of the potential applied to the control sub-unit of the first conversion and the logic state of a second input being the value of the potential applied to the control sub-unit of the second conversion.

The description also refers to a logic computation architecture including at least two logic devices as previously described, the logic computation architecture satisfying at least one of the following properties:
a first property according to which the first arm of one of the two logic devices is coincident with the second arm of the other logic device, and
a second property according to which the second arm of one of the two logic devices is connected to an electrical control sub-unit of one of the two conversions.

### BRIEF DESCRIPTION OF THE DRAWINGS

The features and advantages of the invention will appear upon reading the following description, given only as an example, but not limited to, and making reference to the enclosed drawings, wherein:

FIG. 1 is a schematic representation of an example of a logic device with the directions of current indicated for two distinct cases (to the left and to the right, respectively),

FIG. 2 is a graph showing the change of the resistance variation as a function of the angle formed by the field with respect to the current in the case of two-dimensional gases of SrTiO₃,

FIG. 3 is a schematic representation of the different cases corresponding to the different possible values when the logic device of FIG. 1 performs an XNOR function,

FIG. 4 is a schematic representation of the different cases corresponding to the different possible values when another logic device performs an XNOR function,

FIG. 5 is a schematic representation of the different cases corresponding to the different possible values when another logic device performs a NOR function, and

FIG. 6 is a representation of an example of a logic architecture with multiple concatenated logic devices.

### DETAILED DESCRIPTION OF EMBODIMENTS

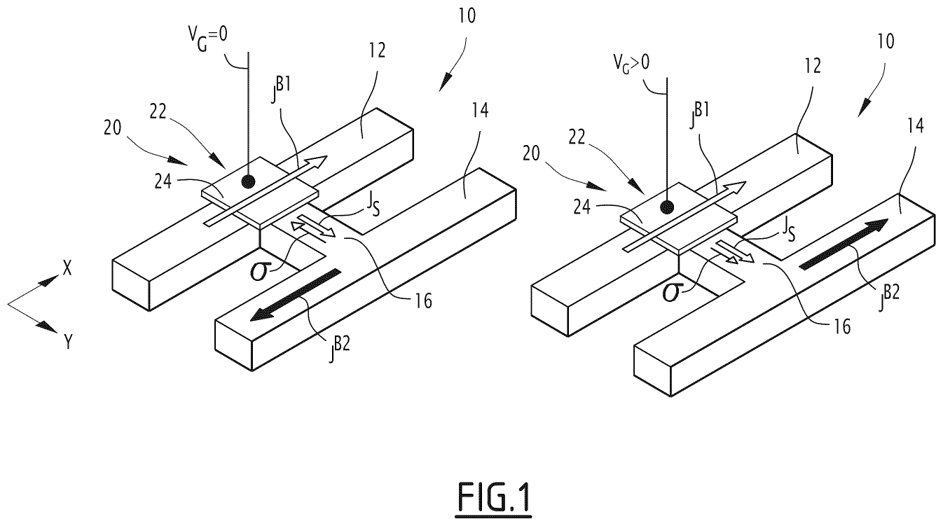

A logic device 10 is illustrated in FIG. 1 for two distinct cases.

The logic device 10 is adapted to perform a logic operation on two logic inputs to obtain a logic output, the logic output then being the result of the logic operation applied to the two logic inputs.

The logic device 10 includes a first arm 12, a second arm 14 and a channel 16 connecting the first arm 12 to the second arm 14.

The first arm 12 extends along a first direction X. The first arm 12 is adapted to letting therethrough a charging current denoted by J^{B1}. The charging current J^{B1} is indicated in the two cases shown in FIG. 1, each case corresponding to an identical direction of travel of the charging current.

By convention, herein, when a charging current moves along the direction X upwards in FIG. 1, the charging current is positive (the notation +X will be adopted hereinafter) whereas when a charging current moves downwards in FIG. 1, the charging current is negative (the notation −X will be adopted hereinafter).

The second arm 14 extends along the first direction X and is thus parallel to the first arm 12.

The second arm 14 is also adapted to let flow therethrough a charging current denoted by J^{B2}. The charging current is indicated in the two cases shown in FIG. 1, each case corresponding to a direction of travel of the charging current (along −X or +X).

The channel 16 is along a second direction Y, the second direction Y being perpendicular to the first direction X.

The channel 16 includes three zones, a first zone of contact with the first arm 12, a second zone of contact with the second arm 14 and a central zone connecting the two zones of contact.

Since the arms of FIG. 1 have the same extent along the second direction Y, the arms and the channel 16 form an H.

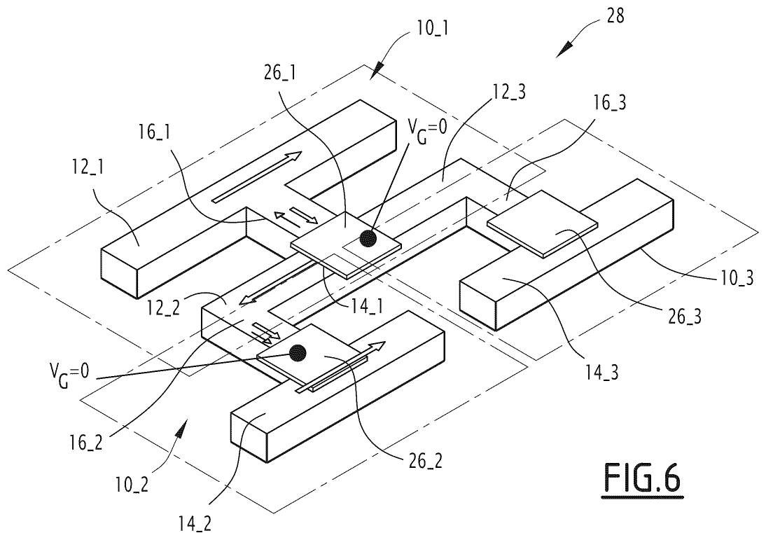

Nevertheless, it is possible that the arms do not have the same extent along the second direction Y, as can be seen in particular in FIG. 6.

The first arm 12 and the channel 16 are adapted to perform a first conversion.

The first conversion is the conversion of a charge current J^{B1} circulating in the first arm 12 into a spin current denoted by J^{s} circulating in the channel 16.

The first conversion is thus a charge-spin conversion at the intersection between the first arm 12 and the channel 16, i.e. in the first contact zone.

The spin current generated is represented for each of the cases and has the same direction. However, as will be subsequently discussed in detail, the direction of the spins is opposite in both cases.

The second arm 14 and the channel 16 are adapted to perform a second conversion.

The second conversion is the conversion of a spin current Jₛ circulating in the channel 16 into a charge current J^{B2} circulating in the second arm 14. The second conversion is thus a spin-charge conversion at the intersection between the channel 16 and the second arm 14, i.e. in the second contact zone.

To perform the two conversions, the channel 16 has a sufficient spin diffusion length.

Typically, a length comprised between 10 nanometers and 10 microns (μm) is a sufficient spin diffusion length.

With regard to the materials, a plurality of cases can be envisaged.

According to a first example, the arms 12 and 14 and the channel 16 are made of the same material.

According to another example, the arms 12 and 14 are made of a first material, the contact zones are made of the first material and the central zone is made of a second material distinct from the first material.

The advantage of such an example is that it becomes possible to separately optimize the conversion efficiency and the spin diffusion length, at the cost of optimizing the interfaces between the two materials involved and in particular the transparency thereof to spin currents.

Each of the aforementioned materials are advantageously chosen from the following list:
an oxide, more particularly SrTiO₃ or KTaO₃,
a III-V semiconductor material, preferably InAs or InSb,
a II-VI semiconductor material, preferably HgTe or CdTe,
transition metal dichalcogenides, preferably WS₂, WSe₂, PtSe₂, MoTe₂ or MoSe₂, combined, if appropriate, with a layer of graphene or of another two-dimensional material.
topologic insulators, preferably (Bi,Sb)₂(Se,Te)₃ or (Bi,Sb).

In the above list, two-dimensional electron gases based on oxides such as SrTiO₃ or KTaO₃, or based on III-V semiconductors such as INAS or InSb are particularly interesting examples.

The logic device 10 further comprises a control unit 20 for controlling the direction of the charging current flowing through the second arm 14.

The control unit 20 includes a sub-unit for the electrical control of the first conversion 22.

The control sub-unit 22 is adapted to control the direction of the charge current flowing through the second arm 14 by controlling the direction of the spins of the spin current by electrically controlling the first conversion.

To this end, according to the example shown in FIG. 1, the control sub-unit 22 includes a voltage source (not shown) and an electrical contact 24.

The contact 24 is in contact with the first contact zone and the voltage source controls the potential of the contact 24.

The contact 24 is a multilayer formed at least by an insulating layer and a metal layer, the insulating layer resting on the arm 12, and more precisely the first contact zone.

It is possible to envisage that the insulating material forming the insulating layer is a simple dielectric material or a ferroelectric material, which imparts a non-volatile character to the operation of the device.

When the insulating material is a ferroelectric material, the contact 24 may be called a ferroelectric contact. The ferroelectric material may advantageously be chosen from the list consisting of BaTiO₃, Pb(Zr,Ti)O₃, BiFeO₃, (Hf,Zr)O₂, and poly(vinylidene fluoride) (also denoted by the acronym PVDF).

The control sub-unit 22 is thereby an electrostatic or ferroelectric gate positioned at the intersection between the first arm 12 and the channel 16.

It will now be explained how the control sub-unit 22 controls the direction of the spins of the spin current by electrically controlling the first conversion.

As can be seen in FIG. 1, the logic device 10 comprises a basic structure which is here an H-shaped Hall bar.

During the application of a charge current J^{B1} in the input arm, the spin-orbit coupling induces the conversion (partial or total) of the charge current into a transverse spin current Jₛ which will circulate in channel 16. The conversion mechanism may typically be a spin Hall effect mechanism or an Edelstein effect mechanism.

Depending on the case, the orientation of the spins in channel 16 may vary (generally the spins are perpendicular to the plane of the layer in the case of the spin Hall effect and in the plane and parallel to Jₛ in the case of the Edelstein effect), but in both cases a spin current Jₛ flows through the channel 16. At the intersection with the output arm, the spin current Jₛ is converted back into a charge current by the inverse spin Hall effect or by the inverse Edelstein effect.

Taking as an example the case of the direct and inverse Edelstein effects, the direction of the (planar) spins conveyed by Jₛ in the channel 16 depends on the sign of the charging current in the first arm 12. The conversion of the spin current into a charging current at the second arm 14 depends on the direction of the spins, the output current changing sign with the sign of the current in the first arm 12.

For a given sign of the current in the first arm 12, the direction of the spins generated in the channel 16 depends on the sign of the conversion coefficient, i.e. on the Hall spin angle θ^{SHE} in the case of the Hall spin effect, or on the Edelstein length λ^{IEE} in the case of the inverse Edelstein effect. Generally, the amplitude and sign of the conversion coefficient are fixed by the electronic structure and hence are specific to each material. For example, Pt has a positive Hall spin angle θ^{SHE} and Ta has a negative Hall spin angle θ^{SHE}.

The applicant was able to show that the amplitude and sign of the conversion coefficient can be modified by the application of a gate voltage. Thereof leads to an accumulation or depletion of the number of carriers and to a variation of the position of the Fermi level in the band structure. The Fermi level can thereby be positioned as desired at the bands with different orbital characters, with conversion properties of one sign or another.

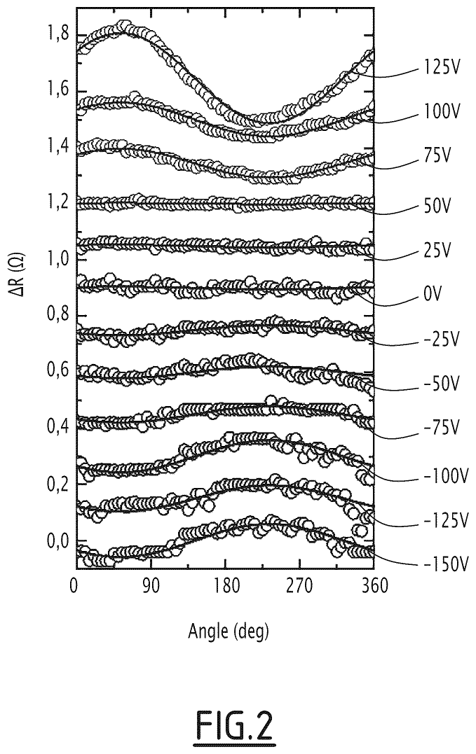

FIG. 2 presents magnetotransport results illustrating the modulation of the amplitude and of the sign of the charge-spin conversion by the Edelstein effect in two-dimensional gases of SrTiO₃.

In such a case, the application of a charging current generates, via the Edelstein effect, a transverse spin density which leads to the observation of a unidirectional magnetoresistance effect: the resistance under a magnetic field applied transversely to the current is different depending on whether the transverse field is parallel or antiparallel to the spin density generated by the Edelstein effect.

If the resistance is measured as a function of the angle formed by the field with respect to the current, a sinusoidal dependence is obtained, with extrema at 90 and 270 degrees corresponding to the two directions of the transverse field with respect to the current.

As shown in FIG. 2, the sign of the dependency changes when a gate voltage is applied by using a back gate.

The change in sign reflects the change in sign of the charge-spin conversion coefficient.

Such effect makes it possible to control the spin-charge and/or charge-spin conversion by electrostatic or ferroelectric gates.

The application of a gate voltage VG leads to a change in the charge-spin conversion coefficient. As a result, without changing the input current, the direction of the spins in the channel 16 is changed, and the output current changes sign.

It is such principle that allows the first conversion control sub-unit 22 to operate.

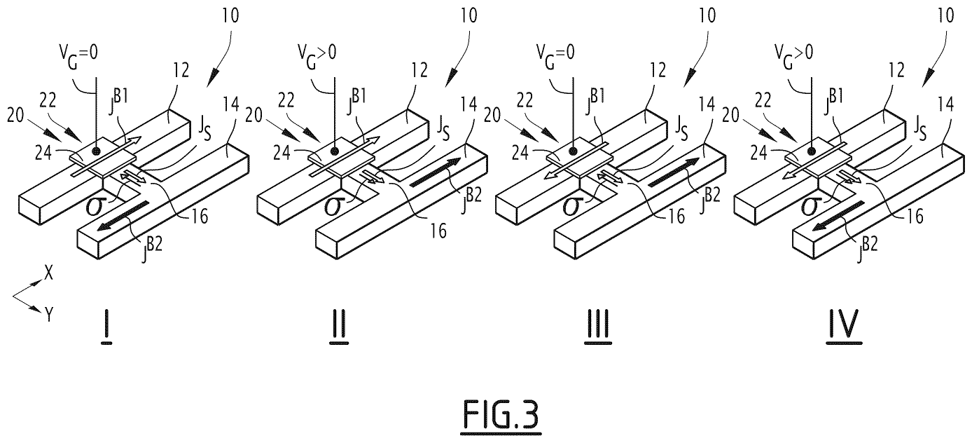

As the control is very easy, as a result, very low energy consumption can be contemplated for fulfilling any type of logic function as will be shown by describing FIGS. 3 to 5.

Moreover, the operation becomes bidirectional so that the concatenation of the logic devices 10 is possible as illustrated in FIG. 6.

With such a control sub-unit, the logic device 10 can e.g. be used to make an XNOR logic gate. The XNOR function is the logic complement of the exclusive-OR gate as shown schematically in FIG. 3 which shows the various cases I to IV.

In such example, the two logic inputs are, on the one hand, the direction of the charging current in the first arm 12 and, on the other hand, the voltage VG applied to the contact. The logic output is the direction of the charging current in the second arm 14.

Thereof corresponds to the logic table that follows.

TABLE 1

| Logic input | J^{B1} < 0 | J^{B1} > 0 |
|---|---|---|
| states | (logic state 0) | (logic state 1) |
| V_{G} = 0 | Case III | Case I |
| (logic state 0) | J^{B2} > 0 (logic state 1) | J^{B2} < 0 (logic state 0) |
| V_{G} > 0 | Case IV | Case II |
| (logic state 1) | J^{B2} < 0 (logic state 0) | J^{B2} > 0 (logic state 1) |

In the configuration which has just been described, the first arm 12 is an input arm and the second arm 14 is an output arm.

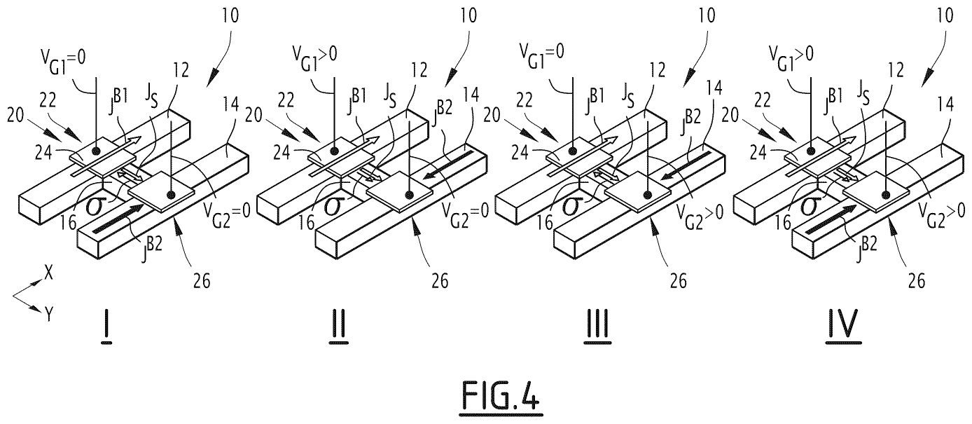

With reference to FIG. 4, another example of a logic device 10 is proposed.

In addition to the elements of the logic device 10 shown in FIG. 1, the logic device 10 includes a second conversion control sub-unit 26 (hereinafter, more simply, second control sub-unit 26)

The second control sub-unit 26 is adapted to control the direction of the charging current by an electrical control of the second conversion.

From a structural point of view, the second control subunit 26 is similar to the first control subunit (the first conversion control subunit) except that the contact is positioned on the other intersection (channel 16 and second arm 14).

As a result, an XNOR function can be performed in a different way.

In such a case, the two logic inputs are on the one hand the voltage V_{G1} applied to the contact of the first control sub-unit 22 and on the other hand the voltage V_{G2} applied to the contact of the second control sub-unit 26 and the logic output is the direction of the charging current in the second arm 14.

Thereof corresponds to the following logic table:

TABLE 2

| Logic input | V_{G2} = 0 | V_{G2} > 0 |
|---|---|---|
| states | (logic state 0) | (logic state 1) |
| V_{G1} = 0 | Case I | Case III |
| (logic state 0) | J^{B2} > 0 (logic state 1) | J^{B2} < 0 (logic state 0) |
| V_{G1} > 0 | Case II | Case IV |
| (logic state 1) | J^{B2} < 0 (logic state 0) | J^{B2} > 0 (logic state 1) |

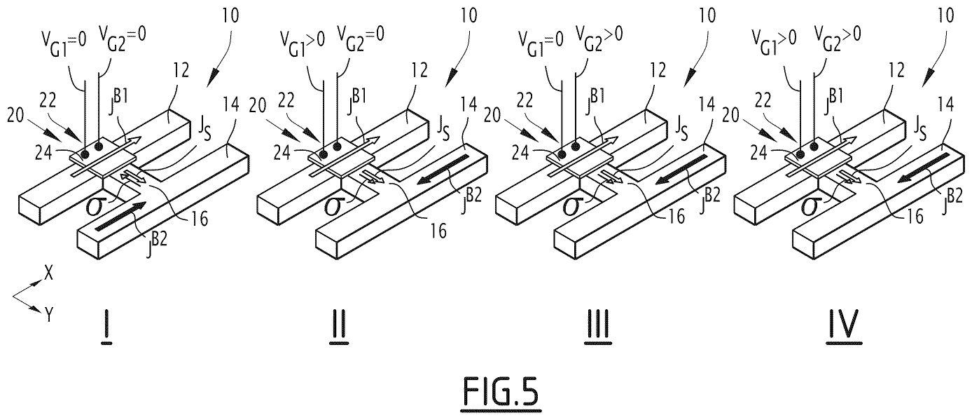

With reference to FIG. 5, another example of a logic device 10 is proposed.

In such example, instead of having a single voltage source, the first conversion control sub-unit 22 comprises two separate current sources connected to the contact.

There is no second control subunit in said example.

In such case, the two logic inputs are on the one hand the current I_{G1} applied to the contact and on the other hand the current I_{G2} applied to the same contact. The output is the direction of the charging current in the second arm 14. It is assumed that the application of at least one of the two input currents induces a change of sign of the conversion.

As a result, a NOR function, i.e. a “non-OR” function can be performed.

Thereof corresponds to the following logic table:

TABLE 3

| Logic input | I_{G2} = 0 | I_{G2} > 0 |
|---|---|---|
| states | (logic state 0) | (logic state 1) |
| I_{G1} = 0 | Case I | Case III |
| (logic state 0) | J^{B2} > 0 (logic state 1) | J^{B2} < 0 (logic state 0) |
| I_{G1} > 0 | Case II | Case IV |
| (logic state 1) | J^{B2} < 0 (logic state 0) | J^{B2} > 0 (logic state 1) |

It should be noted that such a NOR gate is a universal gate. In fact, it is possible to produce all the other Boolean logic gates by combining NOR gates.

FIG. 6 shows an example of a logic computation architecture 28 that can be obtained by using three concatenated logic devices 10, identified in FIG. 6 by a reference sign_1, _2 and _3.

The first logic device 10_1 is a device according to FIG. 1 including a second conversion subunit 26_1 replacing the first conversion subunit.

The second and third logic devices are also devices according to FIG. 1 including a second conversion subunit 26_2 or 26_3 as a replacement of the first conversion subunit but wherein the first arm 12_2 or 12_3 extends only on one side with respect to the channel 16 so that the devices have the shape of an H from which a branch is missing.

In the example, the first arm 12-2 and 12-3 of the second and third logic devices coincides with the second arm 14_1 of the first logic device 10_1.

It is also possible to concatenate the devices by connecting the second arm 14 of a first device 10 to the electrical contact 24 of a second device 10. Thereof can serve to perform other logic functions, the output of the first device 10 controlling the sign of the conversion in the second device 10.

The concatenation of logic devices 10 thus makes it possible to perform logic operations while conserving low energy consumption.

1. A logic device comprising:
a first arm extending along a first direction and letting a charging current flow therethrough;
a second arm extending along the first direction and letting a charging current flow therethrough;
a channel connecting said first arm to said second arm, the channel being along a second direction perpendicular to the first direction, the channel comprising three zones, namely:
a first zone of contact with said first arm, arm;
a second zone of contact with said second arm; and
a central zone connecting said two zones of contact, said first arm, said second arm and the channel performing a first conversion in said first zone of contact and a second conversion in said second zone of contact, the first conversion being conversion of a charging current flowing through said first arm, into a spin current flowing through the channel, and the second conversion being conversion of a spin current flowing through the channel, into a charging current flowing through said second arm arm; and
a control unit controlling the direction of the charging current flowing in said second arm, the control unit comprising at least one electrical control sub-unit of one of the two conversions.

2. The logic device according to claim 1, wherein a control sub-unit of said at least one electrical control sub-unit comprises a control sub-unit of the first conversion and controls the direction of the charging current flowing through said second arm by controlling the direction of the spin current spins by an electrical control of the first conversion.

3. The logic device of claim 2, wherein said control sub-unit for the first conversion includes a voltage source and an electrical contact, the electrical contact being in contact with said first contact zone, the voltage source controlling the potential of the electrical contact.

4. The logic device according to claim 1, wherein a control sub-unit of said at least one electrical control sub-unit comprises a control sub-unit of the second conversion and is adapted to control the direction of the charging current by an electrical control of the second conversion.

5. The logic device according to claim 4, wherein said control sub-unit for the second conversion comprises a voltage source and an electrical contact, the electrical contact being in contact with said second contact zone, the voltage source controlling the potential of the electrical contact.

6. The logic device according to claim 3, wherein the electrical contact comprises a multilayer formed at least by an insulating layer and a metal layer, the insulating layer resting on said arm and said channel.

7. The logic device according to claim 3, wherein the electrical contact rests on a portion of said channel and on a portion of said arm.

8. The logic device to according to said claim 1, wherein arm and said channel form an H.

9. The logic device according to claim 1, wherein said arms and said channel are made of the same material.

10. The logic device according to claim 1, wherein said arms are made of a first material, said contact zones are made of a second material and said channel is made of a third material distinct from said first material and from said second material.

11. The logic device according to claim 9, wherein each material is chosen from:
an oxide,
a III-V semiconductor material,
a II-VI semiconductor material,
transition metal dichalcogenides, and
topologic insulators.

12. The logic device according to claim 1, wherein the logic device performs a logic operation on two logic inputs to obtain a logic output, the state of the logic output being the direction of the current circulating in said second arm,
the logic state of a first input is value of a potential applied to a control sub-unit and the logic state of a second input is the direction of the current circulating in said first arm, or
the logic state of a first input is the value of a current applied to a control sub-unit and the logic state of a second input is the value of another current applied to a control sub-unit, or
the logic state of a first input is the value of the potential applied to the control sub-unit of the first conversion and the logic state of a second input is the value of the potential applied to the control sub-unit of the second conversion.

13. A logic computation architecture (28) including at least two logic devices according to claim 1, the logic computation architecture satisfying at least one of the following properties:
the first arm of one of said two logic devices is coincident with the second arm of the other logic device, and
the second arm of one of said two logic devices is connected with an electrical control sub-unit of one of the two conversions.

14. The logic device according to claim 6, wherein said channel is made of a ferroelectric material.

15. The logic device according to claim 14, wherein the ferroelectric material is chosen from the group consisting of BaTiO₃, Pb(Zr,Ti)O₃, BiFeO₃, (Hf,Zr)O₂, and poly(vinylidene fluoride).

16. The logic device according to claim 11, wherein each material is chosen from the group consisting of SrTiO₃, KTaO₃, InAs, InSb, HgTe, CdTe, S₂, WSe₂, PtSe₂, MoTe₂, MoSe₂ and (Bi,Sb)₂ (Se,Te)₃.
